(19) United States
(12) Patent Application Publication
(10) Pub. No.: US 2026/0338846 A1
(43) Pub. Date: Oct. 29, 2026

(54) Self-Localizing Test Antenna Methodology for Near Field Alignment of Multiple Radio Frequency Receivers and Transmitters

(71) Applicant: U.S. Army Space and Missile Defense Command, Huntsville, AL (US)

(72) Inventor: David M. Bates, Wonthella (AU)

(21) Appl. No.: 19/190,977

(22) Filed: Apr. 28, 2025

(51) Int. Cl. G01R 29/08; G01R 35/00

(52) U.S. Cl. CPC G01R 29/0871; G01R 35/005

(57) ABSTRACT

A self-localizing test antenna apparatus used for calibrating a concert of radio frequency transmitters and/or receivers in phase and amplitude to one another with no dependence on the precise location of the source calibration equipment. The test source location is determined electrically at time of use by mathematically cancelling out the mechanical location so that the exact location of the source calibration equipment is not needed. Thus, by ensuring mechanical alignment of the source calibration equipment test horns to each other, laser survey equipment is not needed.

### STATEMENT OF GOVERNMENT INTEREST

The invention described herein may be manufactured, used, and licensed by or for the U.S. Government for government purposes without payment of any royalties thereon.

### BACKGROUND

The present disclosure relates generally to antenna systems and more particularly to near-field antenna calibration.

An antenna array includes multiple array elements that are antennas coupled to respective receivers and transmitters. The array elements are located in fixed relation to one another. Multiple radio frequency (RF) transmitters and/or receivers are used in radios and radar to detect angle of arrival (AoA) of RF signals, either from a source or reflected off a target, respectively, and to steer RF signals in a desirable direction such as towards an intended communications receiver or to concentrate RF signals on a target spatially. Techniques can also be employed to avoid illuminating spatial locations with RF signals or avoid receiving RF signals from a specific location. These techniques avoid multi-path reflections of a desired signal or strong interferences such as radio transmitters and Electronic Attack (EA).

Calibrations are usually performed periodically during the life of an antenna to correct for changes that can introduce errors in transmitting and receiving and that degrade performance of the antenna array. Some radar systems require calibration using a test source placed very close to an antenna under test (AUT). A widely used method for calibrating an antenna array uses near-field measurements and mathematical algorithms to align the receivers. Typically, when using near-field measurements, a test source or test horn is placed in the near field of the antenna array and sequentially positioned to face each one of the array elements. At each test position, a test signal is transmitted from the test horn to the corresponding antenna element or AUT and a measurement is made.

The alignment of the receivers electrically in phase and amplitude is paramount for accurate signal processing. A typical test horn needs to be laser calibrated to ensure a known mechanical source location. The prior art utilizes careful mechanical precision and positioning using laser survey equipment, for example, which is done intermittently, and not necessarily at a scheduled time of service. Also, repeated mechanical alignments with a laser survey or other accurate mechanism may be needed.

Also important for accurate signal processing is the distance of the test horn from the AUT. The closer the traditional external test horn is to the AUT, the less accurate the signal processing results will be. Close test sources can increase the mechanical positioning accuracy requirements past mechanical precision limits. For example, a 0.1 mm mechanical misalignment of a test horn at 3 m will cause a larger AUT angle misalignment than 0.1 mm when the test horn is at 30 m from the AUT; when tracking an object at 300 km, the angle offset would be 10 m for a test horn located 3 m from the AUT versus 1 m for the test horn located 30 m from the AUT. Thus, the closer state-of-the-art test sources are to the AUT, the more precise the mechanical positioning accuracy or intratest horn alignment must be to prevent an antenna pattern misalignment.

Typical calibration is prone to mechanical misalignments, complications, limits of precision, and errors. Therefore, what is needed is a calibration method and system for improving the accuracy of near-field antenna array calibration.

### SUMMARY

Presented herein is a self-localizing technique that can be used to calibrate a concert of RF transmitters and/or receivers in phase and amplitude to one another with no dependence on the precise location of the source calibration equipment.

The location of the source calibration equipment is typically known before calibration begins and is included in the mathematical algorithms. However, the technique described herein solves the test source location electrically at time of use by mathematically cancelling out the mechanical location so that the exact location of the source calibration equipment is not needed.

Thus, by ensuring mechanical alignment of the source calibration equipment test horns to each other, laser survey equipment is not needed. This also has the advantage that the test horns can be moved as long as they are rigid enough to one another.

### BRIEF DESCRIPTION OF THE DRAWINGS

Various aspects and advantages of the invention will become apparent from the following detailed description, taken in conjunction with the accompanying drawings. The drawings are not necessarily drawn to scale. In the drawings:

FIG. 1 is a diagram of a self-localizing test antenna apparatus, according to an embodiment of the invention;

FIG. 2 is a diagram of the self-localizing test antenna apparatus of FIG. 1 and an antenna under test;

FIG. 3 is a block diagram of the self-localizing test antenna apparatus and the antenna under test of FIG. 2, including a controller;

FIG. 4 is a diagram of a self-localizing test antenna apparatus in accordance with another embodiment of the invention;

FIG. 5 is a diagram of the self-localizing test antenna apparatus of FIG. 4 and an antenna under test;

FIG. 6 is a flowchart illustrating an exemplary method for performing near-field antenna array calibration in accordance with the embodiment of FIGS. 1 and 2; and

FIG. 7 is a flowchart illustrating an exemplary method for performing near-field antenna array calibration in accordance with the embodiment of FIGS. 4 and 5.

### DETAILED DESCRIPTION OF THE PREFERRED EMBODIMENTS

As used herein, the phrase “antenna under test” or “AUT” refers to an element of an antenna array. To calibrate an antenna array, such as a phased array, the amplitude and phase of the RF signal incident to each AUT is determined in either absolute or relative terms between the AUTs. To accomplish this, the invention uses a self-localizing test antenna apparatus having multiple test antennas, with one of the antennas being designated a reference test antenna, to calculate the absolute distance between each of the test antennas (i.e., test horns) and each AUT. By calculating the distances in real time, the self-localizing test antenna apparatus does not need to be precisely positioned with respect to each AUT.

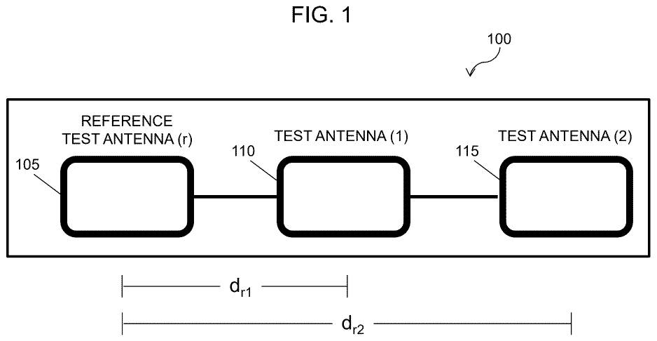

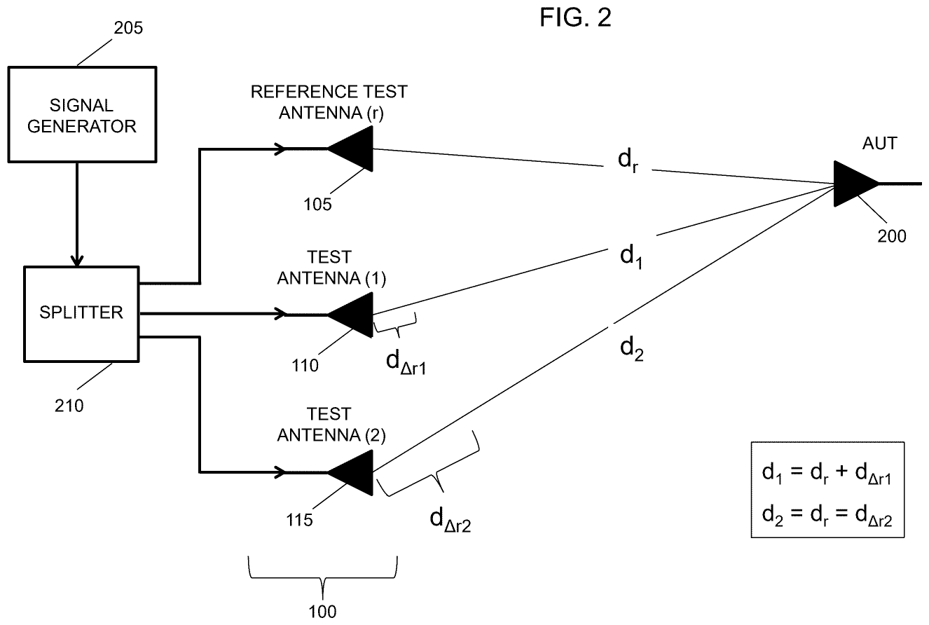

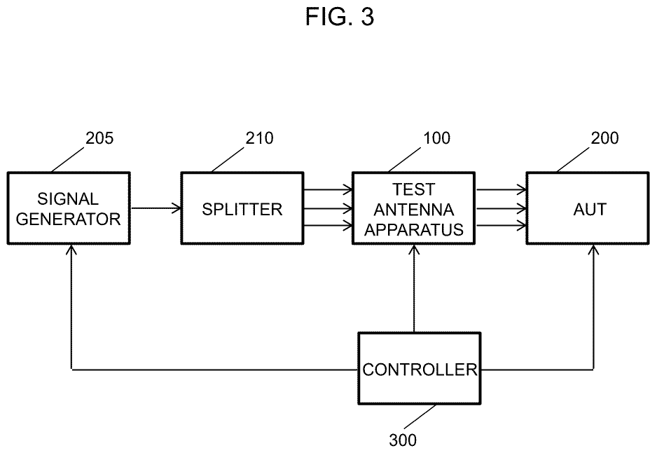

FIGS. 1, 2, and 3 show a self-localizing test antenna apparatus 100 and system, according to an embodiment of the invention, having at least three test antennas configured in a row. For ease of illustration, three test antennas are shown in FIGS. 1 and 2: reference test antenna 105 (also referred to herein as “reference test antenna r”), test antenna 110 (also referred to herein as “test antenna 1”), and test antenna 115 (also referred to herein as “test antenna 2”). While an antenna array can have many antenna elements, only one AUT 200 is shown in FIGS. 2 and 3 for ease of illustration. The three test antennas r, 1, and 2 are held in fixed relation to one another and are used to determine an absolute distance of the AUT 200 to the reference test antenna r. The mechanical distance from the reference test antenna r to test antenna 1 is designated dᵣ₁ and the mechanical distance from the reference test antenna r to test antenna 2 is designated dᵣ₂. An RF source (signal generator) 205 generates a reference or test signal, having a desired range of frequencies, that is transmitted from the test antennas r, 1, and 2 to the AUT 200.

The test antennas r, 1, and 2 must either be fed with the same RF feed signal, which can be accomplished by matched cabling after splitting the single test signal from the RF source between the test antennas, or the differences in phase and amplitude of the test antennas must be known and corrected. In the embodiment shown in FIGS. 2 and 3, a splitter 210 is used to split the test signal.

The first step in determining the absolute distance from the reference test antenna r to the AUT 200 is to calculate relative difference in distances from the AUT 200 to the test antennas r, 1, and 2. This is accomplished by measuring across the desired range of frequencies for the combination of the AUT 200 and each of the test antennas r, 1, and 2, and measuring the phase shift with respect to frequency for each pairing of test antennas (i.e., reference test antenna r with test antenna 1 and reference test antenna r with test antenna 2). That is, the phase differences between the AUT 200 and the reference test antenna r across the given range of frequencies are compared to the phase differences between the AUT 200 and test antenna 1 for the same range of frequencies, and the phase differences between the AUT 200 and the reference test antenna r across the given range of frequencies are compared to the phase differences between the AUT 200 and test antenna 2 for the same range of frequencies. The phase differences are used in equations 1 and 2 below to determine the relative differences in distance between the AUT 200 and the test antennas r, 1, and 2:

θ_{Δf,r,1}=2π·mod(d_{Δr1},λ_{f}) (Eq. 1)

θ_{Δf,r,2}=2π·mod(d_{Δr2},λ_{f}) (Eq. 2)
where θ_{Δf,r,1} [symbol] [0, 2π] is the measured phase shift difference between test antennas r and 1, r≠1, at frequency f; d_{Δr1} is the relative difference in distance between (1) the AUT 200 and reference test antenna r and (2) the AUT 200 and test antenna 1; λ_{f} is the wavelength at frequency f; θ_{Δf,r,2} [symbol] [0, 2π] is the measured phase difference between test antennas r and 2, r≠2, at frequency f; and d_{Δr2} is the relative difference in distance between (1) the AUT 200 and reference test antenna r and (2) the AUT 200 and test antenna 2.

Given the measured phase shift difference for each frequency, equations 1 and 2 are used to calculate d_{Δr1} and d_{Δr2}. Care should be taken to sample frequencies at close enough intervals, or non-linearly spaced frequency lists, to ensure no under-sampling of the phase shift. An under-sampled phase shift from a longer than expected measurement distance might appear, for example, as

$$\frac{π}{6}$$

when the shift was really

$$2 π + \frac{π}{6} = \frac{13 π}{6}$$

in modular arithmetic. Measurements will give a relative phase value and the absolute phase shift must be calculated by adding the correct integer multiple of 2π to the relative phase value, which is often referred to as “unwrapping the phase.” Advance knowledge of the predicted distances can help solve the phase unwrap in calculating relative distances, which can leverage known antenna mechanical positioning and test horn positioning.

Next, the absolute distance from the reference test antenna r to the AUT 200 is calculated using equation 3 below, which relies on the calculated relative distances and the known mechanical spacing of the test antennas 1 and 2 from the reference test antenna r:

$${d}_{r} = \frac{{d}_{r 2} {d}_{Δ r 1}^{2} - {d}_{r 1} {d}_{Δ r 2}^{2} - {d}_{r 2} {d}_{r 1}^{2} + {d}_{r 1} {d}_{r 2}^{2}}{2 ( {d}_{r 1} {d}_{Δ r 2} - {d}_{r 2} {d}_{Δ r 1} )} \qquad ( Eq . 3 )$$

where dᵣ is the absolute distance from the AUT 200 to the reference test antenna r; dᵣ₁ is the mechanical distance from the reference test antenna r to test antenna 1; d_{Δr1} is the relative difference in distance, which is calculated using equation 1 and the phase unwrap procedure above, between (1) the AUT 200 and the reference test antenna r and (2) between AUT 200 and test antenna 1; dᵣ₂ is the mechanical distance from the reference test antenna r to test antenna 2; and d_{Δr2} is the relative difference in distance, which is calculated using equation 2 and the phase unwrap procedure above, between (1) the AUT 200 and the reference test antenna r and (2) between the AUT 200 and test antenna 2. Then, referring to FIG. 2, the absolute distance d₁ between the AUT 200 and test antenna 1 is dᵣ+d_{Δr1} and the absolute distance d₂ between the AUT 200 and test antenna 2 is dᵣ+d_{Δr2}.

After determining the distance of the AUT 200 from the reference test antenna r of the self-localizing test antenna apparatus 100 (i.e., geolocating the AUT 200), the AUT 200 can then be tested according to conventional test procedures and requirements, such as testing across a different range of frequencies of concern. The steps above are repeated for each remaining AUT in the antenna array. In the embodiment shown in FIG. 3, a controller 300 is coupled to the AUT 200; the test antennas r, 1, and 2; and the signal generator 205 to perform the measurements and calculations resulting from transmission of the test signal.

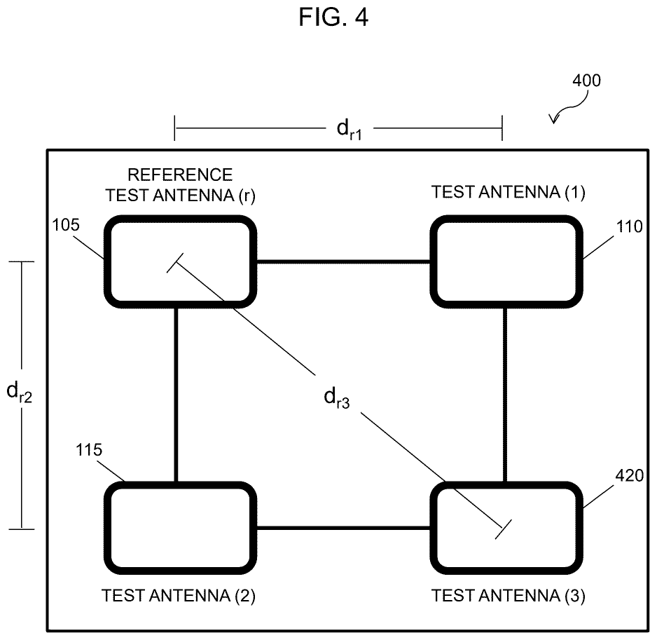

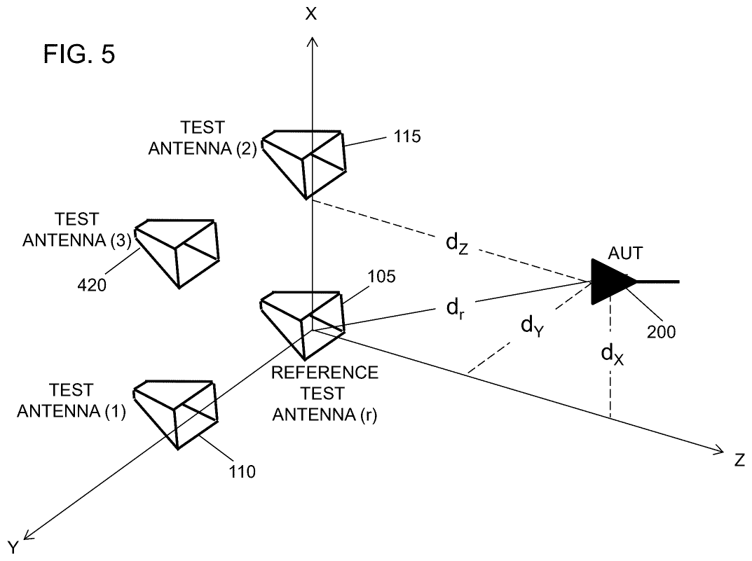

This absolute distance measurement from the AUT 200 does not calculate the spatial position of the AUT 200 in three dimensions. In another embodiment of the invention, as shown in FIGS. 4 and 5, a self-localizing test antenna apparatus 400 includes a fourth test antenna 420 (also referred to herein as “test antenna 3”). The four test antennas r, 1, 2, and 3, arranged in a square configuration, are used to determine a three-dimensional location of the AUT 200 with respect to the four test antennas r, 1, 2, and 3. For the square configuration of test antennas, the absolute distance dᵣ from the AUT 200 to the reference test antenna r is calculated using equation 4 below, which relies on the relative differences in distance between the AUT 200 and the test antennas r, 1, 2, and 3, which are calculated using the phase unwrap procedure above:

$${d}_{r} = \frac{{d}_{Δ r 1}^{2} + {d}_{Δ r 2}^{2} - {d}_{Δ r 3}^{2}}{2 ( {d}_{Δ r 3} - {d}_{Δ r 1} - {d}_{Δ r 2} )} \qquad ( Eq . 4 )$$

The mechanical distances between the test antennas r, 1, 2, and 3 in the square configuration are not required for calculating the absolute distance between the reference test antenna r and the AUT 200 in this embodiment, but they are required if the three-dimensional location of the AUT 200 with respect to the reference test antenna r is desired. The two-dimensional offsets dₓ and d_{y} of the AUT 200 projected onto the plane of test antennas r, 1, 2, and 3 in the direction of the measured test antenna (i.e., reference test antenna r) are calculated using equations 5 and 6 as follows:

$${d}_{x} = \frac{2 {d}_{r} {d}_{Δ r 1} + {d}_{Δ r 1}^{2} - {d}_{r 1}^{2}}{- 2 {d}_{r 1}} \qquad ( Eq . 5 )$$

$${d}_{y} = \frac{2 {d}_{r} {d}_{Δ r 2} + {d}_{Δ r 2}^{2} - {d}_{r 2}^{2}}{- 2 {d}_{r 2}} \qquad ( Eq . 6 )$$

where dₓ is the offset of the AUT 200 in the direction of test antenna 2, d_{y} is the offset of the AUT 200 in the direction of test antenna 1, dᵣ₁ is the mechanical distance between the reference test antenna r and test antenna 1, dᵣ₂ is the mechanical distance between the reference test antenna r and test antenna 2, and dᵣ=dᵣ₂ for the square configuration.

The AUT 200 out of plane distance is the Pythagorean distance d_{z} into the page per FIG. 4 and is calculated using equation 7:

$${d}_{z} = \sqrt{{d}_{r}^{2} - {d}_{x}^{2} - {d}_{y}^{2}} \qquad ( Eq . 7 )$$

The steps above are repeated for each remaining AUT in the antenna array. After determining the distance of the AUT 200 from the reference test antenna r of the self-localizing test antenna apparatus 400 (i.e., geolocating the AUT 200), the AUT 200 can then be tested according to conventional test procedures and requirements. Then the testing process is repeated for the other AUTs in the antenna array.

As stated above, all test antennas must either be fed with the same RF feed signal, which can be accomplished by matched cabling after splitting the single test signal from the RF source between the test antennas, or the differences in phase and amplitude of the test antennas must be known and corrected. Differences may be measured and corrected, or a hybrid matching calculation can be applied such as is disclosed in U.S. patent application Ser. No. 16/509,638, filed Jul. 12, 2019, now U.S. Pat. No. 11,482,779, the entire disclosure of which is hereby incorporated by reference herein. The equipment/hardware and software used to generate, measure, and process the RF signals is not shown, but is known in the art.

If absolute amplitude and phase incident to each AUT is desired, then phase and amplitude at the reference test antenna r must be determined through calibration or self-measurement. Then the phase and amplitude incident at each AUT can be calculated by using the known reference phase and amplitude from the reference test antenna r and adjusting by the calculated absolute distance between the reference test antenna r and each AUT.

Alternatively, if the goal is to align multiple AUTs to each other, phase and amplitude at the reference test antenna may be omitted by setting one AUT as a reference value and aligning the other AUTs based on the differences in absolute path length. In other words, in this case it is not necessary to know the absolute phase at any given AUT. One AUT may be designated as a reference and the other AUTs may be aligned relative to it based on the differences in absolute path length. Note that the distance from a given AUT to the reference test antenna r affects the amplitude as a function of the reference test antenna pattern, and is a tradeoff.

The accuracy of the measurements is proportional to the signal-to-noise ratio (S/N) of the measurements, the accuracy of the mechanical distance between the test antennas, and the spacing distance between test antennas. Also, the accuracy of the measurements is inversely proportional to the distance from a given AUT to a reference test antenna. Using multiple test antennas in a row or a grid with respect to the configurations of the embodiments described above can correct for some of these complications by giving an array of estimates and averaging. An error budget is useful in determining the accuracy requirements and test configuration requirements with respect to number and locations of test antennas. Also, knowledge of mechanical alignment between AUTs can be utilized to avoid measuring every AUT with every calibration, especially after initial alignments.

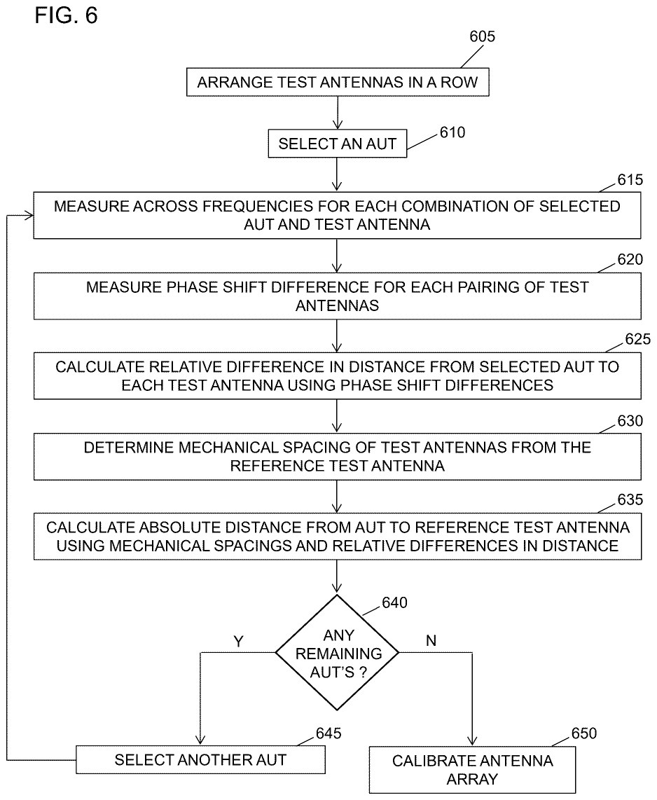

FIG. 6 is a flowchart illustrating a method for performing near-field antenna array calibration in accordance with the embodiment of the invention shown in FIGS. 1 and 2. First, the test antennas r, 1, and 2 of the self-localizing test antenna apparatus 100 are arranged in a row (block 605). Then an AUT is selected from the antenna array for which absolute distance from the reference test antenna r will be determined (block 610). The RF source generates the test signal having the desired range of frequencies, which is transmitted from the test antennas r, 1, and 2 to the AUT 200. Measure across the selected frequencies for the combination of the AUT 200 and each of the test antennas r, 1, and 2 (block 615).

The phase shift difference for each pairing of test antennas (i.e., reference test antenna r with test antenna 1 and reference test antenna r with test antenna 2) for each selected frequency is measured (block 620). Using the phase shift differences and the phase shift equations (equations 1 and 2) above, calculate the relative difference in distance d_{Δr1} between (1) the selected AUT and the reference test antenna r and (2) the selected AUT and test antenna 1, and the relative difference in distance d_{Δr2} between (1) the selected AUT and the reference test antenna r and (2) the selected AUT and test antenna 2 (block 625).

At block 630, determine the mechanical spacing of test antenna 1 from the reference test antenna r (dᵣ₁) and the mechanical spacing of test antenna 2 from the reference test antenna r (dᵣ₂). Calculate the absolute distance from the selected AUT to the reference test antenna r (dᵣ) using equation 3 above, the mechanical spacings dᵣ and dᵣ₂, and the relative differences in distance d_{Δr1} and d_{Δr2} (block 635).

Determine whether the absolute distances to the reference test antenna r have been determined for all AUTs (block 640). If not, select another AUT from the antenna array (block 645) and repeat from block 615.

After all the absolute distances to the reference antenna r have been determined for all the AUTs, calibrate the antenna array using conventional test procedures (block 650).

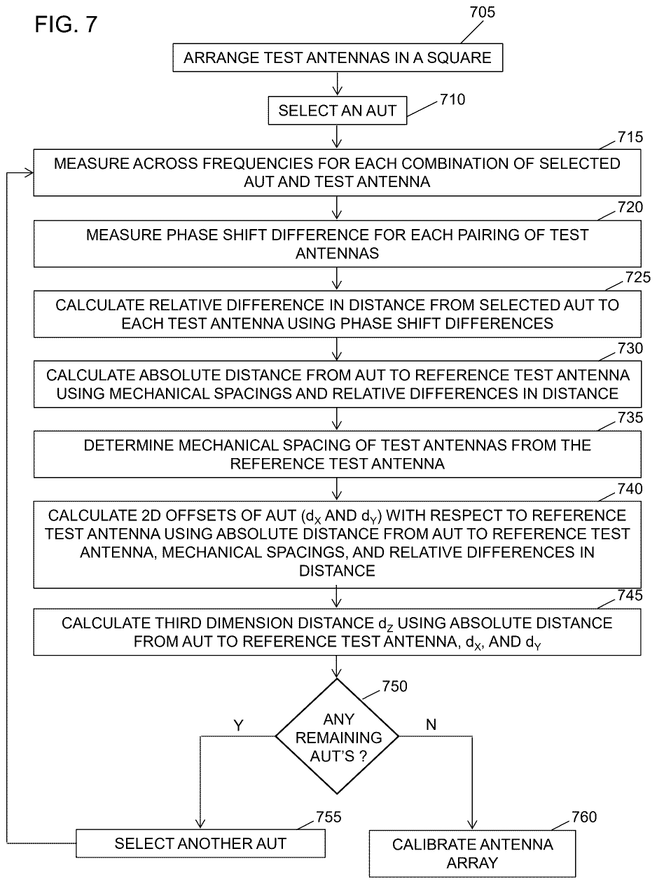

FIG. 7 is a flowchart illustrating a method for performing near-field array antenna calibration in accordance with the embodiment of the invention shown in FIGS. 4 and 5. First, the test antennas r, 1, 2, and 3 of the self-localizing test antenna apparatus 400 are arranged in a square (block 705). Then an AUT is selected from the antenna array for which absolute distance from the reference test antenna r will be determined (block 710). The RF source generates the test signal having the desired range of frequencies, which is transmitted from the test antennas r, 1, and 2 to the AUT 200. Measure across the selected frequencies for the combination of the AUT 200 and each of the test antennas r, 1, and 2 (block 715).

Next, the phase shift difference for each pairing of test antennas (i.e., reference test antenna r with test antenna 1 and reference test antenna r with test antenna 2) for each selected frequency is measured (block 720). Using the phase shift differences and the phase shift equations (equations 1 and 2) above, and the applying the phase shift equations to test antenna 3 so that θ_{Δf,r,3}=2π·mod(d_{Δr,3}, λ_{f}), calculate the relative difference in distance dam between (1) the selected AUT and the reference test antenna r and (2) the selected AUT and test antenna 1, the relative difference in distance d_{Δr2} between (1) the selected AUT and the reference test antenna r and (2) the selected AUT and test antenna 2, and the relative difference in distance d_{Δr3} between (1) the selected AUT and the reference test antenna r and (2) the selected AUT and test antenna 3 (block 725). Calculate the absolute distance from the selected AUT to the reference test antenna r (dᵣ) using equation 4 above and the relative differences in distance d_{Δr1}, d_{Δr2}, and d_{Δr3} (block 730).

Determine the mechanical spacings from the reference test antenna r to the test antennas adjacent to the reference test antenna r (block 735). That is, determine the mechanical spacing of test antenna 1 from the reference test antenna r (dᵣ₁) and the mechanical spacing from test antenna 2 from the reference test antenna r (dᵣ₂).

Then, calculate the two-dimensional offset d_{X} of the selected AUT in the direction of test antenna 2, and the two-dimensional offset d_{Y} of the selected AUT in the direction of test antenna 1 using equations 5 and 6 respectively and the absolute distance dᵣ from the selected AUT to the reference test antenna r, the mechanical spacings dᵣ₁ and dᵣ₂, and the relative differences in distance d_{Δr1} and d_{Δr2} (block 740). Calculate the third three-dimensional distance, d_{z}, using equation 7, the absolute distance dᵣ from the selected AUT to the reference test antenna r, and the two-dimensional offsets d_{X} and d_{Y} (block 745).

Determine whether the three-dimensional locations have been determined for all AUTs (block 750). If not, select another AUT from the antenna array (block 755) and repeat from block 615. Finally, after the three-dimensional locations have been determined for all the AUTs, calibrate the antenna array using conventional test procedures (block 760).

Alternative test antenna arrangements may be used as will be apparent to persons of skill in the art, and the number of test antennas can vary depending on the particular application. In addition to antenna array calibration, the concepts and techniques discussed above may be extended for use in applications other than array calibration. For example, the invention has application in radar, telemetry receiving antennas, 5G, and other telecommunication arrays, and to make on-site antenna calibrations and factory calibrations. The technique described herein may also be used in phased array beam steering, electronic protection (EP), spatial domain multiplex communications, and in determining angle of arrival (AoA) of incident RF signals.

Although the specific actions shown in the flowcharts follow a definite order, it should be appreciated that variations may be made without departing from the spirit and scope of the underlying concepts, as persons of ordinary skill in the art will readily understand. For example, in some embodiments, additional steps may be included, and certain steps may be performed in parallel, in a different order, omitted, or combined. In some implementations, the methods may be embodied as instructions stored on a tangible computer readable medium that can be executed by a computing device or system.

Thus, the self-localizing technique described herein is advantageous in that it can be used to calibrate a concert of RF transmitters and/or receivers in phase and amplitude to one another with no dependence on the precise location of the source calibration equipment test horns. Also, by ensuring mechanical alignment of the test horns to each other, laser survey equipment is not needed, and the self-localizing test antenna apparatus can be moved rather than remaining stationary.

While the foregoing written description of the invention enables one of ordinary skill to make and use what is described herein, those skilled in the art will understand and appreciate the existence of variations, combinations, and equivalents of the disclosed embodiments and methods. The invention should therefore not be limited by the above description, but by all embodiments and methods within the scope and spirit of the invention as disclosed.

What is claimed is:

1. A self-localizing test antenna system, comprising:
an antenna array having a plurality of antenna elements, one of the antenna elements being designated an antenna under test (AUT);
a signal generator that generates a test signal having a desired range of frequencies;
three or more test antennas configured in a row, with one of the test antennas being designated a reference test antenna r, the test antennas transmitting the test signal to the AUT; and
a controller coupled to the AUT, the test antennas, and the signal generator to perform the measurements and calculations resulting from transmission of the test signal,
wherein the controller calculates an absolute distance from the AUT to the reference test antenna r using mechanical distances from the reference test antenna r to the other test antennas, and relative differences in distance between the AUT and the test antennas, and
wherein the controller calculates the absolute distances in real time so that the self-localizing test antenna apparatus does not need to be precisely positioned with respect to the AUT.

2. The system of claim 1, wherein the controller measures across the desired range of frequencies for a combination of the AUT and each of the test antennas, and measures phase shift with respect to frequency for each pairing of the test antennas.

3. The system of claim 2, wherein the other test antennas include a first test antenna 1 and a second test antenna 2 and the relative difference in distance d_{Δr1} between (1) the AUT and the reference test antenna r and (2) the AUT and the first test antenna 1 and the relative difference in distance d_{Δr2} between (1) the AUT and the reference test antenna r and (2) the AUT and the second test antenna 2 are solved for according to the following equations:
θ_{Δf,r,1}=2π·mod(d_{Δr1},λ_{f})
θ_{Δf,r,2}=2π·mod(d_{Δr2},λ_{f})
where:
θ_{Δf,r,1} [symbol] [0, 2π] is the measured phase shift difference between the reference test antenna r and the first test antenna 1, r≠1, at frequency f,
λ_{f} is a wavelength at frequency f, and
θ_{Δf,r,2} [symbol] [0, 2π] is the measured phase shift difference between the reference test antenna r and the second test antenna 2, r≠2, at frequency f.

4. The system of claim 3, wherein the absolute distance dr from the AUT to the reference test antenna r is calculated as follows:
$${d}_{r} = \frac{{d}_{r 2} {d}_{Δ r 1}^{2} - {d}_{r 1} {d}_{Δ r 2}^{2} - {d}_{r 2} {d}_{r 1}^{2} + {d}_{r 1} {d}_{r 2}^{2}}{2 ( {d}_{r 1} {d}_{Δ r 2} - {d}_{r 2} {d}_{Δ r 1} )}$$
where:
dᵣ₁ is the mechanical distance from the reference test antenna r to the first test antenna 1,
d_{Δr1} is the relative difference in distance between (1) the AUT and reference test antenna r and between (2) the AUT and the first test antenna 1,
dᵣ₂ is the mechanical distance from the reference test antenna r to the second test antenna 2, and
d_{Δr2} is the relative difference in distance between (1) the AUT 200 and the reference test antenna r and between (2) the AUT and the second test antenna 2.

5. The system of claim 4, wherein the absolute distances from the AUT to test antenna 1 (d₁) and test antenna 2 (d₂) are respectively calculated according to:
d₁=dᵣ+d_{Δr1}
d₂=dᵣ+d_{Δr2}
where:
dᵣ is the absolute distance from the AUT to the reference test antenna r,
d₁ is the absolute distance from the AUT to test antenna 1, and
d₂ is the absolute distance from the AUT to test antenna 2.

6. The system of claim 1 further comprising a signal splitter coupled to the signal generator that splits and feeds the test signal to the test antennas.

7. A self-localizing test antenna system, comprising:
an antenna array having a plurality of antenna elements, one of the antenna elements being selected as an antenna under test (AUT);
a signal generator that generates a test signal having a desired range of frequencies;
four test antennas configured in a square shape to determine a three-dimensional location of the AUT with respect to the test antennas, one of the test antennas being designated a reference test antenna, the test antennas transmitting the test signal;
a controller coupled to the AUT, the test antennas, and the signal generator to perform the measurements and calculations resulting from transmission of the test signal,
wherein the controller calculates an absolute distance from the AUT to the reference test antenna r using relative differences in distance between the AUT and the test antennas, and
wherein the controller calculates the absolute distance in real time so that the self-localizing test antenna apparatus does not need to be precisely positioned with respect to the AUT.

8. The system of claim 7, wherein the controller measures across the desired range of frequencies for a combination of the AUT and each of the test antennas, and measures phase shift with respect to frequency for each pairing of the test antennas.

9. The system of claim 8, wherein the other test antennas include a first test antenna 1, a second test antenna 2, and a third test antenna 3, and the relative difference in distance d_{Δr1} between (1) the AUT and the reference test antenna r and (2) the AUT and the first test antenna 1, the relative difference in distance d_{Δr2} between (1) the AUT and the reference test antenna r and (2) the AUT and the second test antenna 2, and the relative difference in distance d_{Δr3} between (1) the AUT and the reference test antenna r and (2) the AUT and the third test antenna 3 are solved for according to the following equations:
θ_{Δf,r,1}=2π·mod(d_{Δr1},λ_{f})
θ_{Δf,r,2}=2π·mod(d_{Δr2},λ_{f})
θ_{Δf,r,3}=2π·mod(d_{Δr3},λ_{f})
where:
θ_{Δf,r,1} [symbol] [0, 2π] is the measured phase shift difference between the reference test antenna r and the first test antenna 1, r≠1, at frequency f,
λ_{f} is a wavelength at frequency f,
θ_{Δf,r,2} [symbol] [0, 2π] is the measured phase shift difference between the reference test antenna r and the second test antenna 2, r≠2, at frequency f, and
θ_{Δf,r,3} [symbol] [0, 2π] is the measured phase shift difference between the reference test antenna r and the third test antenna 3, r≠3, at frequency f.

10. The system of claim 9, wherein the absolute distance dᵣ from the AUT to the reference test antenna r is calculated as follows:
$${d}_{r} = \frac{{d}_{Δ r 1}^{2} + {d}_{Δ r 2}^{2} - {d}_{Δ r 3}^{2}}{2 ( {d}_{Δ r 3} - {d}_{Δ r 1} - {d}_{Δ r 2} )}$$
where:
d_{Δr1} is the relative difference in distance between (1) the AUT and the reference test antenna r and between (2) the AUT and the first test antenna 1,
d_{Δr2} is the relative difference in distance between (1) the AUT and the reference test antenna r and between (2) the AUT and the second test antenna 2, and
d_{Δr3} is the relative difference in distance between (1) the AUT and the reference test antenna r and between (2) the AUT and the third test antenna 3.

11. The system of claim 10, wherein two-dimensional offsets dX and dY of the AUT projected onto a plane of the test antennas in a direction of the reference test antenna r are calculated according to the following equations:
$${d}_{x} = \frac{2 {d}_{r} {d}_{Δ r 1} + {d}_{Δ r 1}^{2} - {d}_{r 1}^{2}}{- 2 {d}_{r 1}}$$
$${d}_{y} = \frac{2 {d}_{r} {d}_{Δ r 2} + {d}_{Δ r 2}^{2} - {d}_{r 2}^{2}}{- 2 {d}_{r 2}}$$
where:
d_{X} is the offset of the AUT in the direction of the second test antenna 2,
d_{Y} is the offset of the AUT in the direction of the first test antenna 1,
dᵣ₁ is a mechanical distance between the reference test antenna r and the first test antenna 1, and
dᵣ₂ is a mechanical distance between the reference test antenna r and the second test antenna 2, and dᵣ₁=dᵣ₂ for the square configuration.

12. The system of claim 11, wherein an AUT out of plane distance d_{z} is calculated as follows:
$${d}_{z} = \sqrt{{d}_{r}^{2} - {d}_{x}^{2} - {d}_{y}^{2}}$$
where:
dᵣ is the absolute distance from the AUT to the reference test antenna r,
d_{X} is the offset of the AUT in the direction of the second test antenna 2, and
d_{Y} is the offset of the AUT in the direction of the first test antenna 1.

13. The system of claim 7 further comprising a signal splitter coupled to the signal generator that splits and feeds the test signal to the test antennas.

14. A method for calibrating an antenna array using self-localization of a test antenna apparatus, comprising:
(a) arranging three or more test antennas in a row and designating one of the test antennas as a reference test antenna r;
(b) selecting an antenna under test (AUT) from an antenna array having a plurality of antenna elements;
(c) generating a test signal having a desired range of frequencies and splitting the test signal among the test antennas;
(d) transmitting the test signal from the test antennas to the AUT;
(e) measuring across the desired range of frequencies for a pairing of the AUT and each respective test antenna;
(f) measuring phase shift with respect to frequency for each pairing of the test antennas for each selected frequency;
(g) calculating relative differences in distance from the AUT to the test antennas using the measured phase shift differences;
(h) calculating absolute distances from the AUT to each of the test antennas using mechanical distances from the reference test antenna r to each of the other test antennas and the relative differences in distance;
(i) calibrating the AUT based on the absolute distances of the test antennas from the AUT; and
(j) repeating steps (b) through (i) for each of the remaining antenna elements.

15. The method of claim 14, wherein the other test antennas include a first test antenna 1 and a second test antenna 2 and said measuring across a desired range of frequencies for a pairing of the AUT and each respective test antenna and measuring phase shift with respect to frequency for each pairing of the test antennas comprises:
comparing the phase differences between the AUT and the reference test antenna r across the desired range of frequencies to the phase differences between the AUT and the test antenna 1 for the same range of frequencies; and
comparing the phase differences between the AUT and the reference test antenna r across the desired range of frequencies to the phase differences between the AUT and the test antenna 2 for the same range of frequencies.

16. The method of claim 15, wherein said determining relative differences in distance from the AUT to the test antennas comprises:
calculating a relative difference in distance between (1) the AUT and the reference test antenna r and (2) the AUT and the test antenna 1; and
calculating a relative difference in distance between (1) the AUT and the reference test antenna r and (2) the AUT and the test antenna 2.

17. The method of claim 16, wherein said calculating a relative difference in distance between (1) the AUT and the reference test antenna r and (2) the AUT and the test antenna 1 and calculating a relative difference in distance between (1) the AUT and the reference test antenna r and (2) the AUT and the test antenna 2 comprises applying the following equations:
θ_{Δf,r,1}=2π·mod(d_{Δr1},λ_{f})
θ_{Δf,r,2}=2π·mod(d_{Δr2},λ_{f})
where:
θ_{Δf,r,1} [symbol] [0, 2π] is the measured phase difference between the reference test antenna r and the test antenna 1, r≠1, at a frequency f,
d_{Δr1} is the relative difference in distance between (1) the AUT and the reference test antenna r and (2) the AUT and the test antenna 1,
λ_{f} is wavelength at frequency f,
θ_{Δf,r,2} [symbol] [0, 2π] is the measured phase difference between the reference test antenna r and the test antenna 2, r≠2, at frequency f, and
d_{Δr2} is the relative difference in distance between (1) the AUT and reference test antenna r and (2) the AUT and the test antenna 2.

18. The method of claim 17, wherein said calculating absolute distances from the AUT to each of the test antennas using mechanical distances from the reference test antenna r to each of the other test antennas and the relative differences in distance comprises applying the following equation:
$${d}_{r} = \frac{{d}_{r 2} {d}_{Δ r 1}^{2} - {d}_{r 1} {d}_{Δ r 2}^{2} - {d}_{r 2} {d}_{r 1}^{2} + {d}_{r 1} {d}_{r 2}^{2}}{2 ( {d}_{r 1} {d}_{Δ r 2} - {d}_{r 2} {d}_{Δ r 1} )}$$
where:
dᵣ is the absolute distance from the AUT to the reference test antenna r,
dᵣ₁ is the mechanical distance from the reference test antenna r to the test antenna 1,
d_{Δrt} is the relative difference in distance between (1) the AUT and the reference test antenna r and between (2) the AUT and the test antenna 1,
dᵣ₂ is the mechanical distance from the reference test antenna r to the test antenna 2,
d_{Δr2} is the relative difference in distance between (1) the AUT and the reference test antenna r and between (2) the AUT and the test antenna 2; and
wherein an absolute distance d₁ from the AUT to the test antenna 1 is d₁=dᵣ+d_{Δr1}, and
wherein an absolute distance d₂ from the AUT to the test antenna 2 is d₂=dᵣ+d_{Δr2}.

19. The method of claim 14, further comprising placing the test antennas in a near field of the antenna array.

20. A method for calibrating an antenna array using self-localization of a test antenna apparatus, comprising:
(a) arranging four test antennas in a square shape and designating one of the test antennas as a reference test antenna r;
(b) selecting an antenna under test (AUT) from an antenna array having a plurality of antenna elements;
(c) generating a test signal having a desired range of frequencies and splitting the test signal among the test antennas;
(d) transmitting the test signal from the test antennas to the AUT;
(e) measuring across the desired range of frequencies for a pairing of the AUT and each respective test antenna;
(f) measuring phase shift with respect to frequency for each pairing of the test antennas for each selected frequency;
(g) calculating relative differences in distance from the AUT to the test antennas using the measured phase shift differences;
(h) calculating an absolute distance from the AUT to the reference test antenna r using only the relative differences in distance;
(i) calibrating the AUT based on the absolute distances of the test antennas from the AUT; and
(j) repeating steps (b) through (i) for each of the remaining antenna elements.

21. The method of claim 20, wherein the other test antennas include a first test antenna 1, a second test antenna 2, and a third test antenna 3 and said measuring across a desired range of frequencies for a pairing of the AUT and each respective test antenna and measuring phase shift with respect to frequency for each pairing of the test antennas comprises:
comparing the phase differences between the AUT and the reference test antenna r across the desired range of frequencies to the phase differences between the AUT and the test antenna 1 for the same range of frequencies;
comparing the phase differences between the AUT and the reference test antenna r across the desired range of frequencies to the phase differences between the AUT and the test antenna 2 for the same range of frequencies; and
comparing the phase differences between the AUT and the reference test antenna r across the desired range of frequencies to the phase differences between the AUT and the test antenna 3 for the same range of frequencies.

22. The method of claim 21, wherein said determining relative differences in distance from the AUT to the test antennas comprises:
calculating a relative difference in distance between (1) the AUT and the reference test antenna r and (2) the AUT and the test antenna 1;
calculating a relative difference in distance between (1) the AUT and the reference test antenna r and (2) the AUT and the test antenna 2; and
calculating a relative difference in distance between (1) the AUT and the reference test antenna r and (2) the AUT and the test antenna 3.

23. The method of claim 22, wherein said calculating a relative difference in distance between (1) the AUT and the reference test antenna r and (2) the AUT and the test antenna 1, calculating a relative difference in distance between (1) the AUT and the reference test antenna r and (2) the AUT and the test antenna 2, and calculating a relative difference in distance between (1) the AUT and the reference test antenna r and (2) the AUT and the test antenna 3 comprises applying the following equations:
θ_{Δf,r,1}=2π·mod(d_{Δr1},λ_{f})
θ_{Δf,r,2}=2π·mod(d_{Δr2},λ_{f})
θ_{Δf,r,3}=2π·mod(d_{Δr3},λ_{f})
where:
θ_{Δf,r,1} [symbol] [0, 2π] is the measured phase difference between the reference test antenna r and the test antenna 1, r≠1, at a frequency f,
d_{Δr1} is the relative difference in distance between (1) the AUT and the reference test antenna r and (2) the AUT and the test antenna 1,
λ_{f} is wavelength at frequency f,
Δ_{f,r,2} [symbol] [0, 2π] is the measured phase difference between the reference test antenna r and the test antenna 2, r≠2, at frequency f,
d_{Δr2} is the relative difference in distance between the (1) AUT and reference test antenna r and (2) the AUT and the test antenna 2, and
θ_{Δf,r,3} [symbol] [0, 2π] is the measured phase difference between the reference test antenna r and the test antenna 3, r≠3, at frequency f, and
d_{Δr3} is the relative difference in distance between (1) the AUT and reference test antenna r and (2) the AUT and the test antenna 3.

24. The method of claim 23, wherein said calculating an absolute distance from the AUT to the reference test antenna using only the relative differences in distance comprises applying the following equation:
$${d}_{r} = \frac{{d}_{Δ r 1}^{2} + {d}_{Δ r 2}^{2} - {d}_{Δ r 3}^{2}}{2 ( {d}_{Δ r 3} - {d}_{Δ r 1} - {d}_{Δ r 2} )}$$
where:
dᵣ is the absolute distance from the AUT to the reference test antenna r,
d_{Δr1} is the relative difference in distance between (1) the AUT and the reference test antenna r and between (2) the AUT and the test antenna 1,
d_{Δr2} is the relative difference in distance between (1) the AUT and the reference test antenna r and between (2) the AUT and the test antenna 2,
d_{Δr3} is the relative difference in distance between (1) the AUT and the reference test antenna r and between (2) the AUT and the test antenna 3.

25. The method of claim 24, further comprising calculating a three-dimensional position of the AUT with respect to the reference test antenna r.

26. The method of claim 25, wherein two-dimensional offsets of the AUT projected onto a plane of the test antennas in the direction of the reference antenna r are calculated by applying the following equations:
$${d}_{x} = \frac{2 {d}_{r} {d}_{Δ r 1} + {d}_{Δ r 1}^{2} - {d}_{r 1}^{2}}{- 2 {d}_{r 1}}$$
$${d}_{y} = \frac{2 {d}_{r} {d}_{Δ r 2} + {d}_{Δ r 2}^{2} - {d}_{r 2}^{2}}{- 2 {d}_{r 2}}$$
where:
dₓ is the offset of the AUT in the direction of test antenna 2,
d_{y} is the offset of the AUT in the direction of test antenna 1,
dᵣ₁ is the mechanical distance between the reference test antenna r and test antenna 1,
dᵣ₂ is the mechanical distance between the reference test antenna r and test antenna 2, and
dᵣ₁=dᵣ₂ for the square configuration.

27. The method of claim 26, wherein an AUT out of plane distance d_{z} is calculated by applying the following Pythagorean equation:
$${d}_{z} = \sqrt{{d}_{r}^{2} - {d}_{x}^{2} - {d}_{y}^{2}} .$$

28. The method of claim 20, further comprising placing the test antennas in a near field of the antenna array.
